(19) United States
(12) Patent Application Publication
(10) Pub. No.: US 2021/0247367 A1
(43) Pub. Date: Aug. 12, 2021

(54) WORKFLOW-BASED MODEL OPTIMIZATION METHOD FOR VIBRATIONAL SPECTRAL ANALYSIS

(71) Applicant: ZHEJIANG UNIVERSITY, Zhejiang (CN)

(72) Inventors: Tao LIN, Zhejiang (CN); Jinfan XU, Zhejiang (CN); Yibin YING, Zhejiang (CN)

(73) Assignee: ZHEJIANG UNIVERSITY, Zhejiang (CN)

(21) Appl. No.: 16/973,021

(22) PCT Filed: Jul. 31, 2019
(86) PCT No.: PCT/CN2019/098673

§ 371 Date: Dec. 7, 2020

(30) Foreign Application Priority Data
Aug. 8, 2018 (CN) 201810907269.6

(51) Int. Cl. G01N 29/46; G06N 20/00; G06F 17/18

(52) U.S. Cl. CPC G01N 29/46; G06F 17/18; G06N 20/00

(57) ABSTRACT

A workflow-based model optimization method for vibrational spectral analysis is provided. The method includes: initializing and determining the evaluation indicator for the model in vibrational spectral analysis and the optimization object of this model, and carrying out permutation and combination on preprocessing methods and multivariate analysis methods to obtain method combinations; determining hyper-parameters within the various method combinations and corresponding hyper-parameter space combinations; inputting the training set into the various method combinations and optimizing hyper-parameters to determine optimal hyper-parameters of the method combinations; using the training set for training to obtain model parameters so as to acquire various combined models; inputting the test set into the various combined models, calculating the evaluation indicator value for the various combined models, and selecting the optimal model. According to the disclosure, a workflow is established, avoiding tedious manual operation and subjective judgment, making full use of parallel computing resources.

### BACKGROUND

### Technical Field

The disclosure relates to a model optimization method in the field of spectral analysis, and, in particular, relates to a workflow-based model optimization method for vibrational spectral analysis.

### Description of Related Art

Modern spectral analysis technology has gradually become one of the mainstream technologies for nondestructive testing for products in agriculture, medicine, petroleum, and other industries thanks to its advantages of convenience, fast-speed, low costs, and pollution-free. Nevertheless, due to the complexity and difference of various biological systems, much noise is often included in a vibrational spectrum, and the useful information cannot be simply detected. Therefore, various multivariate analysis methods together with appropriate preprocessing techniques are used to model and analyze the spectrum data. Different multivariate analysis methods, as well as the preprocessing techniques, are suitable for different types of spectrum data and predicted indicators. In actual production, using multiple algorithms is often needed to form a combined model, and hyper-parameters are selected and optimized to find the suitable modeling method. The huge search range of hyper-parameters and the high degree of coupling among algorithms have led to increased difficulty of model optimization, and it takes a lot of manpower and computing resources to find the best model. Moreover, with the advancement of spectrum collection methods, the amount of spectrum data used for analysis increases rapidly. Massive data poses new challenges to model construction. Due to the low efficiency and the strong subjectivity of the traditional method of hyper-parameter optimization based on the background knowledge of a specific field, it may be difficult to determine the optimal hyper-parameters. The traditional method has gradually been unable to adapt to the efficient modeling of large amounts of spectral data. and model optimization needs. At present, various types of spectrum analysis software are available to perform fast modeling through specific analysis methods. Nevertheless, a convenient and efficient workflow for model hyper-parameter optimization and performance comparison among multiple models is not provided. Therefore, a workflow for model optimization in vibrational spectral analysis is particularly required to be developed.

### SUMMARY

The disclosure provides a workflow-based model optimization method for vibrational spectral analysis aiming to provide a highly efficient workflow through cross validation and grid searching, so as to solve the problems of tedious model hyper-parameter optimization and performance comparison of multiple models and lack of systematic workflow in vibrational spectral analysis.

The disclosure can be implemented through the following technical solutions.

A model for vibrational spectral analysis includes preprocessing methods and multivariate analysis methods. The model is mainly formed by two steps sequentially implemented through the preprocessing methods and the multivariate analysis methods. Following steps are adopted for model optimization to obtain the model for optimal vibrational spectral analysis.

In the vibrational spectral analysis model, inputted raw spectrum data is subjected to baseline correction, scatter correction, smoothing, and normalization and the like through the preprocessing methods first. One or multiple multivariate analysis methods are used next to model and analyze the preprocessed spectrum data, and results are outputted. Regarding qualitative analysis, classification algorithms are used as the multivariate analysis methods to model and analyze input spectrum data and output prediction labels. Regarding quantitative analysis, regression algorithms are used as the multivariate analysis methods to model and analyze input spectrum data and output prediction values.

In step 1), evaluation parameters of the model for vibrational spectral analysis and the optimization object of this model are initialized and determined. The optimization object of this model includes the preprocessing methods to be optimized and compared, hyper-parameters and corresponding hyper-parameter spaces to be optimized through each of the preprocessing methods, the multivariate analysis methods to be optimized and compared, hyper-parameters and corresponding hyper-parameter spaces to be optimized through each of the multivariate analysis methods.

In step 2, combine and arrange each preprocessing methods and the multivariate analysis methods provided in step 1) to obtain all possible method combinations.

Select one or more of the preprocessing methods or none, and then combine one or more of the multivariate analysis methods.

In step 3), according to all possible method combinations obtained in step 2) and the hyper-parameters and the corresponding hyper-parameter spaces to be optimized through each of the preprocessing methods and the hyper-parameters and the corresponding hyper-parameter spaces to be optimized through each of the multivariate analysis methods obtained in step 1), determine the combinations of the hyper-parameters and the corresponding hyper-parameter spaces under each of the method combinations.

In step 4), divide the inputted vibrational spectrum data into a training set and a test set.

In step 5), input the vibrational spectrum data of the training set into each of the method combinations, optimizing the hyper-parameters of each of the method combinations in the corresponding hyper-parameter space combinations under each of the method combinations according to the evaluation indicator determined in step 1), and determine the optimal hyper-parameters of the method combinations.

In step 6), input the vibrational spectrum data of the training set into the model established corresponding to the optimal hyper-parameters of the method combinations obtained in step 5) for training, obtain model parameters of the model, and accordingly obtain combined models.

In step 7), input the vibrational spectrum data of the test set into the combined models in step 6), calculate the evaluation indicator value for the combined models according to the evaluation parameters determined in step 1) to act as model performance of the combined models, and select the combined model with the optimal evaluation indicator as the optimal model.

The vibrational spectrum data provided by the disclosure may be derived from the red wine near-infrared spectrum configured to identify the type or quality of red wine, from near-infrared spectrum of tablets configured to measure active substances in medicine and tablets, from the surface enhanced Raman scattering spectrum of bacteria configured to identify the types of bacteria, and so on.

Step 5 further includes the following steps. The optimal hyper-parameters are searched by combining cross validation and grid searching for each of the method combinations. A multi-dimensional grid is established based on all hyper-parameter spaces of the hyper-parameters under the method combination. The hyper-parameter space of each of the hyper-parameters is a set of discrete values. One hyper-parameter corresponds to one dimension. One value in the hyper-parameter space is selected for each of the different hyper-parameters, and the values are combined to form a hyper-parameter combination to act as an intersection point in the grid. Each intersection point represents one hyper-parameter combination, and all hyper-parameter combinations are accordingly obtained. Each intersection point in the grid is traversed. An estimated value of the evaluation indicator for each intersection point is calculated through cross validation to act as the model performance corresponding to each of the hyper-parameter combinations. The intersection point with the optimal estimated value of the evaluation indicator is selected from the grid, and the hyper-parameter combination of the intersection point is treated as the optimal hyper-parameter of the method combination. The step of calculating the estimated value of the evaluation indictor for each intersection point through cross validation further includes the following steps. The training set is divided into a plurality of sub-samples, and a total number of the sub-samples is N. A single sub-sample is selected to act as a validation sub-sample, and the rest of the N-1 sub-samples act as training sub-samples. The training sub-samples are inputted to the model corresponding to each of the hyper-parameter combination for training, and using the validation sub-sample for validation. Each sub-sample is selected to act as the validation sub-sample for cross validation according to the above manner and repeating N times, and such process is repeated N times. Validation results are obtained using the validation sub-sample once after each training, and the average value of the validation results of N times is treated as the estimated value to indicate the model performance corresponding to each hyper-parameter combination.

In the disclosure, in step 3), the grid searching method is adopted for the hyper-parameter space combinations corresponding to the hyper-parameters to be optimized in each of the method combinations to establish the grid to be searched. The grid established through grid searching is traversed through the cross-validation method, and the optimal hyper-parameters of the method combinations can be accurately obtained through such manner.

In step 1), the evaluation indicator in qualitative vibrational spectral analysis is accuracy α, and the evaluation indicator in quantitative vibrational spectral analysis is root-mean-square errors (RMSE). A calculation formula is provided as follows:

$$α = \frac{{n}_{t}}{n} \times 100 \% , \\ R M SE = \sqrt{\frac{{\sum }_{i = 1}^{n} {( {\hat{γ}}_{i} - {γ}_{i} )}^{2}}{n}} ,$$

where n is the total number of samples in the vibrational spectrum data, nₜ is the number of samples which are correctly classified in the qualitative analysis, ŷᵢ is the predicted value of each sample in the quantitative analysis, and yᵢ is the actual value of each sample in the quantitative analysis.

In step 4, the vibrational spectrum data is randomly divided into the training set and the test set, and the ratio of training set to test set is 4:1.

Step 5), step 6), and step 7) are executed in sequence for each of the method combinations. The steps of step 5), step 6), and step 7) are performed in parallel for different method combinations. For the combined models in vibrational spectral analysis which are established corresponding to different method combinations, optimization of the hyper-parameters, model training, and calculation of the evaluation indicator value are simultaneously performed.

In step 7), the method of selecting the optimal model is to select the model with the optimal evaluation indicator value, is to select the combined model with the optimal accuracy in the qualitative analysis, and is to select the combined model with the minimum root-mean-square error in the quantitative analysis.

The preprocessing methods include the asymmetric least squares (ALS) method for baseline correction, the standard normal variate (SNV) method for removing the scattering effect, the Savitzky-Golay filter (SGF) method for removing high frequency noise and smoothing the spectrum data, the mean centering (MC) method for feature normalization, and the like.

The multivariate analysis methods include the partial least squares (PLS) method, the principle component analysis (PCA) method, the linear discriminant analysis (LDA) method, the logistic regression (LogR) method, and the like.

In the disclosure, the hyper-parameters refer to the parameters, whose values are manually set before the training is started and are no longer adjusted during training, in the model established according to the method, such as the window length (sgf_window_length) in the Savitzky-Golay filter (SGF), the polynomial order (sgf_polyorder), the number of latent variables (pls_n_components) in the partial least square (PLS), and the number of principle components (pca_n_components) in the principle component analysis (PCA).

The model parameters refer to the parameters, whose values are continuously adjusted during training and whose values are finally determined after training, in the model established according to the method, such as the coefficient of each monomial in the fitted polynomial in a single sliding window in the Savitzky-Golay filter (SGF), the coefficient of each monomial in the regression equation in the partial least square (PLS), and the coefficient of each monomial in the regression equation in the principle component analysis (PCA).

The disclosure provides a universal processing method for vibrational spectrum data. Regarding the models for vibrational spectral analysis obtained from various sources and methods, when the background knowledge is unknown or no background knowledge is used for any preprocessing of the original vibrational spectrum data, the vibrational spectral analysis model can be directly optimized, and the optimal model can be obtained.

Effects provided by the disclosure includes the following.

In the disclosure, all combined models and corresponding hyper-parameter spaces to be optimized and compared are determined automatically. Therefore, tedious manual operation is avoided, and possible omissions are reduced. The hyper-parameter optimization manner based on cross validation and grid searching is more scientific, and avoids subjective judgment during manual operation. The combining of various methods and the hyper-parameter spaces are determined at the time of initialization, and parallel computing resources can be fully utilized in actual optimization and the training process to achieve efficiency improvement.

To sum up, a universal processing method targeting at the vibrational spectrum data is provided by the disclosure. Tedious manual operation and subjective judgment are avoided, and parallel computing resources are fully utilized. A system model optimization workflow that is not available in traditional spectral analysis software is provided, which solves the problem of lacking systematic model optimization workflow in traditional spectral analysis software.

### BRIEF DESCRIPTION OF THE DRAWINGS

FIG. 1 is the overall flow chart of the method provided by the disclosure.

FIG. 2 is the original near-infrared spectrogram.

FIG. 3 is the diagram of method combinations.

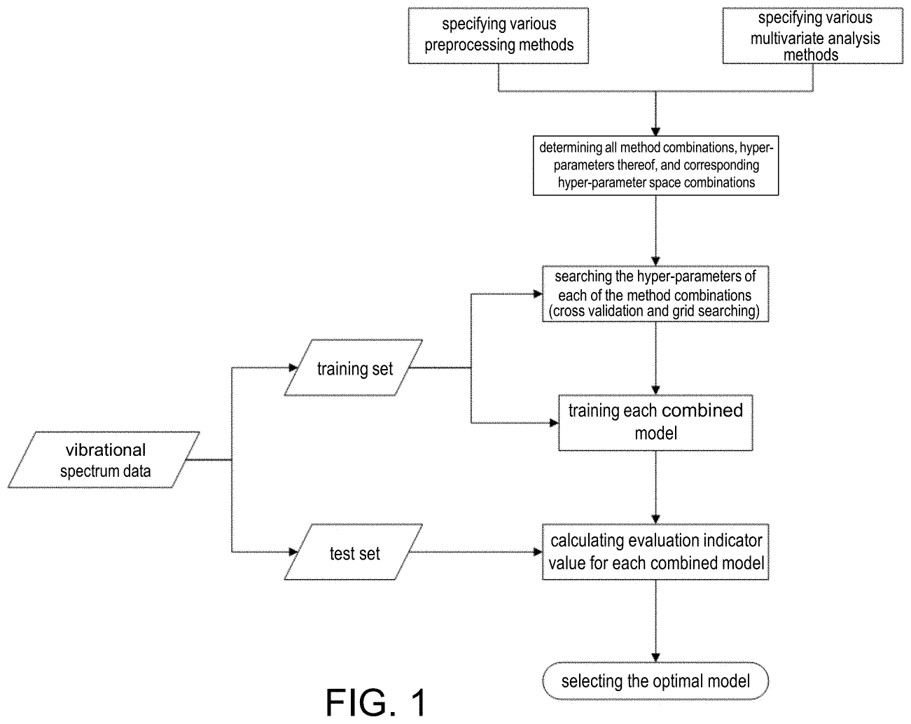

Table 1 is optimal hyper-parameters and corresponding evaluation results of all method combinations.

Table 2 is search ranges of hyper-parameters.

### DESCRIPTION OF THE EMBODIMENTS

The disclosure is further described in detail in combination with the specification and accompanying figures.

The specific embodiments which are implemented according to an overall method provided by the disclosure are provided as follows.

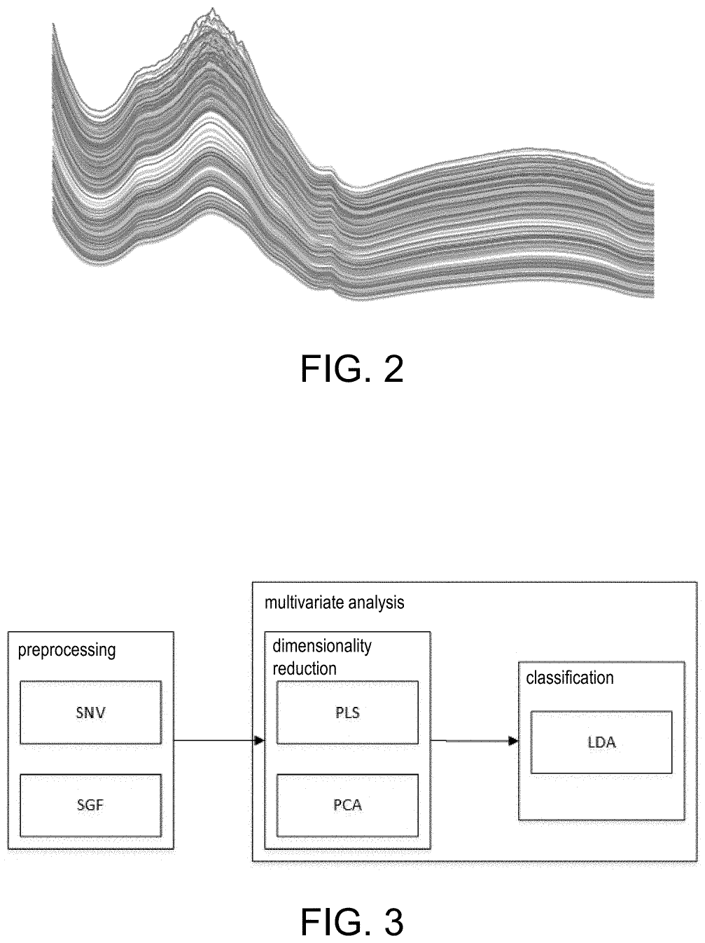

A modeling task for qualitative analysis of Raman spectrum data of tablets is performed. Samples consist of 310 pieces of data in 4 categories, whose near-infrared spectrum is shown in FIG. 2.

Typical method combinations are shown in FIG. 3. Preprocessing methods include the standard normal variate (SNV) method for removing the scattering effect and the Savitzky-Golay filter (SGF) method for removing high frequency noise and smoothing the spectrum data.

Multivariate analysis methods include the partial least squares (PLS) method and the principal component analysis (PCA) method which is dimensionality reduction algorithm as well as the linear discriminant analysis (LDA) method which is classification algorithm.

In the preprocessing step, one combination formed by two preprocessing methods. That is, one or two or none of the preprocessing methods may be selected. For multivariate analysis steps, one of the two dimensionality reduction algorithms is selected in the dimensionality reduction step, and LDA is specified in the classification step.

Therefore, a total of 8 method combinations are to be evaluated, as shown in the first column in Table 1.

TABLE 1

| | | Accuracy | |
|---|---|---|---|
| | | For The | Accuracy |
| Method | | Training | For The |
| Combination | Optimal Hyper-Parameter | Set | Test Set |
| PLS-LDA | {‘pls__n_components’: 6} | 95.16% | 98.39% |
| SGF-PLS-LDA | {‘sgf__window_length’: 5, | 94.76% | 98.39% |
| | ‘sgf__polyorder’: 3, | | |
| | ‘pls__n_components’: 6} | | |
| PCA-LDA | {‘pea__n_components’: 13} | 96.77% | 96.77% |
| SGF-PCA-LDA | {‘sgf__window_length’: 5, | 97.18% | 96.77% |
| | ‘sgf__polyorder’: 2, | | |
| | ‘pea__n_components’: 13} | | |
| SNV-SGF-PLS- | {‘sgf__window_length’: 7, | 98.39% | 93.55% |
| LDA | ‘sgf__polyorder’: 2, | | |
| | ‘pls__n_components’: 12} | | |
| SNV-PLS-LDA | {‘pls__n_components’: 7} | 95.16% | 90.32% |
| SNV-PCA-LDA | {‘pea__n_components’: 13} | 93.95% | 87.10% |
| SNV-SGF-PCA- | {‘sgf__window_length’: 7, | 93.55% | 87.10% |
| LDA | ‘sgf__polyorder’: 3, | | |
| | ‘pea__n_components’: 12} | | |

The hyper-parameters to be optimized and search ranges thereof are shown in Table 2 which includes the window length in SGF (sgf_window_length), the polynomial order (sgf_polyorder), the number of latent variables in PLS (pls_n_components), and the number of principle components in PCA (pca_n_components).

TABLE 2

| | Hyper-Parameter |
|---|---|
| Hyper-Parameter | Search Range |
| sgf__window_length | {5, 7} |
| sgf__polyorder | {2, 3} |
| pls__n_components | [2, 21] |
| pea__n_components | [2, 21] |

The hyper-parameters of the method combinations to be optimized in Table 1 are formed by hyper-parameter combinations of each method to be optimized. A hyper-parameter space of each of the hyper--parameters is a set of possible values, and each hyper-parameter is independent from each other. The hyper-parameter space combination corresponding to the method combination is the set that is established based on the sets of the possible values of all hyper-parameters under each method. For instance, regarding the SGF-PCA-LDA method combination, the hyper-parameters to be optimized include sgf_window_length (the hyper-parameter space is {5, 7}), sgf_polyorder (the hyper-parameter space is {2, 3}), and pca_n_components (the hyper-parameter space is [2, 21]), and the corresponding hyper-parameter space combination is {sgf_window_length: {5, 7}, sgf_polyoorder: {2, 3}, pca_n_components: [2, 21]}.

The sample is randomly divided into a training set and a test set based on a ratio of 4:1. A classification accuracy acts as an evaluation indicator. The hyper-parameters of the method combinations are optimized in the hyper-parameter spaces under the method combinations, and the optimal hyper-parameters of the method combinations are then determined. The following manner can be specifically implemented to determine the optimal hyper-parameter of each single method combination. A multi-dimensional grid is established for all hyper-parameter spaces of the hyper-parameters under the method combination. The hyper-parameter space of each of the hyper-parameters is a set of discrete values. One hyper-parameter corresponds to one dimension. One value in the hyper-parameter space is selected for each of the different hyper-parameters, and the values are combined to form a hyper-parameter combination to act as an intersection point in the grid. Each intersection represents point one hyper-parameter combination, and all hyper-parameter combinations are accordingly obtained. Each intersection point in the grid is traversed. When each intersection point is calculated, the training set is divided into 5 sub-samples. A single sub-sample is selected to act as the validation sub-sample, and the rest of the 4 sub-samples act as training sub-samples. The training sub-samples are inputted to the model corresponding to the hyper-parameter combination of the intersection point for training, and validation is carried out by using the validation sub-sample. Each sub-sample is selected to act as the validation sub-sample for cross validation according to the above manner, and such process is repeated 5 times. Validation results are obtained the validation sub-sample once after each training, and the average classification accuracy rate of the validation results of 5 times is treated as the estimated value to indicate the model performance corresponding to the hyper-parameter combination of each intersection. The intersection point with the optimal estimated value of evaluation indicator is selected from the grid, and the hyper-parameter combination of the intersection point is treated as the optimal hyper-parameter of the method combination.

The vibrational spectrum data of the training set is inputted into the model established corresponding to the optimal hyper-parameter of the method combinations obtained in step 5) for training, model parameters of the model are obtained, and combined models are accordingly obtained.

The vibrational spectrum data of the test set is inputted into the combined models, the classification accuracy is calculated to act as the model performance of the combined models, and the combined model with the optimal evaluation indicator value is selected as the optimal model. According to the results shown in Table 1, the combined models established through the PLS-LDA method combination and the SGF-PLS-LDA method combination exhibit optimal performance. The classification accuracy of the two combined models on the test set is both 98.39%, as shown in the third column in Table 1. The two combined models are the optimal combined models finally selected.

The disclosure can be universally applied. The disclosure not only achieves favorable results in the example of Raman spectrum modeling and analysis task targeting tablet classification, but also exhibits favorable performance in other tests. For instance, in the Raman spectrum modeling and analysis task targeting the classification of Escherichia coli, the optimal combined model exhibiting a classification accuracy of 87% can be quickly established using the workflow presented by this disclosure. The models based on human experience and background knowledge are dependent on manual selection and often difficult to exceed a classification accuracy of 80%. In the near-infrared spectral analysis task targeting the detection of content of soil organic matters, the workflow presented by this disclosure can be used to build the optimal combined model exhibiting an RMSE of 12 g/kg within a few hours. The models based on human experience and background knowledge are dependent on manual selection and often take several times of trial and error time and effort. To obtain a similar accuracy It thus can be seen that, using the universal workflow targeting at the vibrational spectrum data provided by this disclosure, tedious manual operation and subjective judgment are avoided, parallel computing resources are fully used, a systematic model optimization workflow that is not available in traditional spectral analysis software is provided, and the problem of lack of a systematic model optimization workflow found in the traditional spectrum analysis software is solved.

1. A workflow-based model optimization method for vibrational spectral analysis, wherein:
a model for vibrational spectral analysis is mainly formed by two steps sequentially implemented through preprocessing methods and multivariate analysis methods, and following steps are adopted to optimize the model:
step 1): initializing and determining an evaluation indicator for the model in the vibrational spectral analysis and an optimization object of the model, wherein the optimization object of the model comprises the preprocessing methods to be optimized and compared, hyper-parameters and corresponding hyper-parameter spaces to be optimized through each of the preprocessing methods, the multivariate analysis methods to be optimized and compared, hyper-parameters and corresponding hyper-parameter spaces to be optimized through each of the multivariate analysis methods;
step 2): combining and arranging each of the preprocessing methods and the multivariate analysis methods provided in step 1) to obtain all possible method combinations;
step 3): according to all possible method combinations obtained in step 2) and the hyper-parameters and the corresponding hyper-parameter spaces to be optimized through each of the preprocessing methods and the hyper-parameters and the corresponding hyper-parameter spaces to be optimized through each of the multivariate analysis methods obtained in step 1), determining the hyper-parameters and corresponding hyper-parameter space combinations under each of the method combinations;
step 4): dividing inputted vibrational spectrum data into a training set and a test set;
step 5): inputting the vibrational spectrum data of the training set into each of the method combinations, optimizing the hyper-parameters of each of the method combinations in the corresponding hyper-parameter space combinations according to the evaluation indicator determined in step 1), and determining optimal hyper-parameters of the method combinations;
step 6): inputting the vibrational spectrum data of the training set into the model established corresponding to the optimal hyper-parameters of the method combinations obtained in step 5) for training, obtaining model parameters of the model, and accordingly obtaining combined models; and
step 7): inputting the vibrational spectrum data of the test set into the combined models in step 6), calculating the evaluation indicator value for the combined models, and selecting the combined model with an optimal evaluation indicator value as an optimal model.

2. The workflow-based model optimization method for vibrational spectral analysis according to claim 1, wherein step 5) further comprises:
searching for the optimal hyper-parameters by combining cross validation and grid searching for each of the method combinations; and
establishing a multi-dimensional grid based on all hyper-parameter spaces of the hyper-parameters under the method combination, wherein the hyper-parameter space of each of the hyper-parameters is a set of discrete values, and one hyper-parameter corresponds to one dimension, selecting one value in the hyper-parameter space for each of the different hyper-parameters, combining the values to form a hyper-parameter combination to act as an intersection point in the grid, traversing each intersection point in the grid, calculating an estimated value of the evaluation indicator for each intersection through cross validation, selecting the intersection point with the optimal estimated value of the evaluation indicator from the grid, treating the hyper-parameter combination of the intersection point with the optimal estimated value of the evaluation indicator as the optimal hyper-parameters of the method combination;
wherein the step of calculating the estimated value of the evaluation indicator for each intersection point through cross validation further comprises:
dividing the training set into a plurality of sub-samples, wherein a total number of the sub-samples is N, selecting a single sub-sample to act as a validation sub-sample, wherein the rest of the N-1 sub-samples act as training sub-samples, using the training sub-samples for training, using the validation sub-sample for validation; and
selecting each sub-sample to act as the validation sub-sample for cross validation according to the above manner and repeating N times, obtaining validation results using the validation sub-sample once after each training, treating an average value of the validation results of N times as the estimated value of the evaluation indicator.

3. The workflow-based model optimization method for vibrational spectral analysis according to claim 1, wherein in step 1), the evaluation indicator in a qualitative vibrational spectral analysis is accuracy α, the evaluation indicators in a quantitative vibrational spectral analysis is root-mean-square errors (RMSE), and a calculation formula is provided as follows:
$$α = \frac{{n}_{t}}{n} \times 100 \% , \\ R MSE = \sqrt{\frac{{\sum }_{i = 1}^{n} {( {\hat{y}}_{i} - {y}_{i} )}^{2}}{n}} ,$$
wherein n is a total number of samples in the vibrational spectrum data, nₜ is a number of samples which are correctly classified in the qualitative analysis, ŷᵢ is a predicted value of each sample in the quantitative analysis, and yᵢ is an actual value of each sample in the quantitative analysis.

4. The workflow-based model optimization method for vibrational spectral analysis according to claim 1, wherein in step 4, the vibrational spectrum data is randomly divided into the training set and the test set, and a ratio of training set to test set is 4:1.

5. The workflow-based model optimization method for vibrational spectral analysis according to claim 1, wherein step 5), step 6), and step 7) are executed in sequence for each of the method combinations, the steps of step 5), step 6), and step 7) are performed in parallel for different method combinations, and for the combined models in vibrational spectral analysis which are established corresponding to different method combinations, optimization of the hyper-parameters, model training, and calculation of the evaluation indicator value are simultaneously performed.

6. The workflow-based model optimization method for vibrational spectral analysis according to claim 1, wherein in step 7), the method of selecting the optimal model is to select the model with the optimal evaluation indicator value, is to select the combined model with the optimal accuracy in the qualitative analysis, and is to select the combined model with the minimum root-mean-square error in the quantitative analysis.
